(19) United States
(12) Patent Application Publication
(10) Pub. No.: US 2024/0010100 A1
(43) Pub. Date: Jan. 11, 2024

(54) PROCESSING OF STATUS DATA OF A BATTERY FOR AGING ESTIMATION

(71) Applicant: TWAICE Technologies GmbH, Munich (DE)

(72) Inventors: Kaan Atukalp, Munich (DE); Manuel Wanisch, Munich (DE); Arpit Maheshwari, Munich (DE); Cedric Kirst, Munich (DE)

(21) Appl. No.: 18/004,169

(22) PCT Filed: Jul. 5, 2021
(86) PCT No.: PCT/EP2021/068545

§ 371 Date: Jan. 3, 2023

(30) Foreign Application Priority Data
Jul. 3, 2020 (DE) 10 2020 117 609.0

(51) Int. Cl. B60L 58/16; B60L 58/12

(52) U.S. Cl. CPC B60L 58/16; B60L 58/12

(57) ABSTRACT

A method for processing status data of a battery comprises applying an autoencoder artificial neural network to initial status data. Reconstructed status data are obtained therefrom. The method comprises carrying out an aging estimation based on the reconstructed status data in order to obtain a status indicator which is indicative of an aging status of the battery.

### TECHNICAL AREA

Various examples of the disclosure relate in general to techniques for characterizing rechargeable batteries. In particular, various examples of the invention relate to techniques to determine a health status of the battery using one or more machine-learning (ML) algorithms. Various examples of the invention relate in particular to the use of artificial neural networks (ANN) which are designed as autoencoders.

### BACKGROUND

Rechargeable batteries, for example traction batteries of electric vehicles, have a limited service life. This means that one or more aging values, which are indicative of the aging status of the battery, can increase over time and/or as a function of the discharge cycles of the battery. For example, the so-called state of health (SOH) is an aging value or status indicator that is indicative of the aging status of the battery. The SOH is typically determined in conjunction with the capacity and/or the impedance of battery cells of the battery. Typically, the SOH is not directly measurable and is therefore a hidden aging status that has to be determined by inference from other variables.

Status data that describe one or more operating variables of the battery can be used to determine the SOH or another status indicator indicative of a hidden aging status of the battery. An aging estimation can then be carried out based on such status data to obtain the status indicator indicative of the hidden condition of the battery.

Different implementations for the aging estimation are known. One possible implementation is described, for example, in German patent application 10 2020 100 668 of 14 Jan. 2020. A machine-learning algorithm is used therein for characterizing rechargeable batteries. However, a machine-learning (ML) algorithm does not have to be used in all examples. For example, using an empirically parameterized model for the aging estimation, for example using an electrical-thermal simulation in an iteratively alternating method, is known from German patent application 10 2019 111 979 of 8 May 2019.

A common feature of such techniques for estimating aging is that a comparatively large amount of status data of the battery has to be collected. This can be memory intensive. In addition, this can place high demands on the computing capacity for carrying out the aging estimation. Finally, the transmission of such status data from a battery management system of the respective battery, for example via a telematics unit, to a server that carries out the corresponding aging estimation can require a large transmission bandwidth. This is not always practical, for example due to insufficient network coverage and gaps in the status data resulting from such latencies or interruptions.

It has also been observed that conventional techniques for aging estimation are react sensitively to missing or flawed status data. For example, the accuracy of the aging estimation can be reduced, i.e., the status indicator, which is indicative of the hidden aging status of the battery, can sometimes only be determined imprecisely. Flawed or missing status data is observed when, for example, a measuring sensor system fails or status data cannot be transmitted due to restrictions on a radio link.

### BRIEF DESCRIPTION OF THE INVENTION

Therefore, there is a need for improved techniques for aging estimation of a rechargeable battery. In particular, there is a need for such techniques that remedy or mitigate at least some of the above-described limitations and disadvantages.

This object is achieved by means of the features of the independent claims. The features of the dependent claims define embodiments.

Various techniques in conjunction with rechargeable batteries are described hereinafter. In particular, techniques are described that relate to the further data processing of initial status data that describe one or more operating variables of the battery—such as current or voltage at one or more battery cells or temperature, etc. For example, the initial status data can be further processed in conjunction with an aging estimation of the battery. However, it would also be conceivable for the initial status data to be processed further in order to control the operation of the battery. Alternatively or additionally, for example, an error mode of a battery could be triggered based on the further data processing of the initial status data. In this case, the data is further processed in the various examples described herein using an autoencoder ANN.

A method of processing status data of a battery comprises obtaining initial status data. The initial status data describe one or more operating variables of the battery. The method also comprises applying a first neural network to the initial status data so as to obtain an encoded representation of the initial status data. The method furthermore comprises applying a second neural network to the encoded representation of the initial status data so as to obtain reconstructed status data.

A device—for example a server—comprises a processor and a memory. The processor can load and execute program code from the memory. This causes the processor to execute the above-described method for processing status data of a battery.

The reconstructed status data can be used further in various ways. The method could also comprise, for example, carrying out an aging estimation—for example to determine the actual state of health or to predict the state of health—based on the reconstructed status data in order to obtain such a status indicator that is indicative of an aging status of the battery. Alternatively or additionally, the operation of the battery could also be controlled based on the reconstructed status data. For example, a deviation between the reconstructed status data and the initial status data could be detected and the operation of the battery could be controlled based on this deviation. Based on the reconstructed status data or such a deviation, it would also be conceivable to trigger an error mode.

Controlling the battery can comprise, for example, sending control data to the battery or a battery management system, wherein the control data are determined on the basis of the reconstructed status data. For example, it would be conceivable to set a charging management and/or a thermal management of the battery based on the control data.

In particular, it is conceivable that the reconstructed status data also derive hidden operating variables from the one or more operating variables of the initial status data. This means that one or more hidden operating variables, i.e., operating variables not expressly indicated by the initial status data, are reconstructed. It would therefore be possible for the initial status data to comprise at least one time series that specifies the at least one operating variable. The reconstructed status data can then have at least one further time series, which indicate the at least one hidden operating variable; wherein the initial status data do not include this time series, however. As an example, it would be conceivable for the at least one hidden operating variable to relate to a current flow in the battery, while the operating variables indicated by the initial status data relate to the temperature and the voltage in the battery. Thus, for example, it may not be necessary to provide a circuit to measure the current flow in the battery, which is typically comparatively complex (for example, a shunt resistor that is suitably placed has to be provided). If, for example, contact with battery cells is lost, it can sometimes happen that there are no longer any values for the current flow, and even in such a scenario, which involves a temporary failure, it can be helpful to use the reconstructed status data to draw conclusions about operating variables which are not directly observed.

The first neural network can, for example, form an autoencoder network together with the second neural network. Correspondingly, the first neural network can also be referred to as an encoder network and the second neural network can also be referred to as a decoder network.

A computer program or a computer program product or a computer-readable memory medium comprises program code. The program code can be loaded and executed by a processor. When the processor executes the program code, it causes the processor to carry out a method for processing status data. The method comprises obtaining initial status data describing one or more operating variables of the battery. The initial status data describe one or more operating variables of the battery. The method also comprises applying a first neural network to the initial status data so as to obtain an encoded representation of the initial status data. The method furthermore comprises applying a second neural network to the encoded representation of the initial status data so as to obtain reconstructed status data.

A method of processing status data of a battery comprises obtaining initial status data. Initial status data describe one or more operating variables of the battery. The method also comprises applying a first neural network to the initial status data. In this way, an encoded representation of the initial status data is obtained. Furthermore, the method comprises carrying out an aging estimation based on the encoded representation of the initial status data. A status indicator is obtained therefrom, which is indicative of an aging status of the battery. This carrying out of the aging estimation comprises applying a second neural network to the encoded representation of the initial status data.

A device—for example a server—comprises a processor and a memory. The processor can load and execute program code from the memory. This causes the processor to execute the above-described method for processing status data of a battery.

The first neural network can therefore be an encoder ANN of an autoencoder ANN.

A computer program or a computer program product or a computer-readable memory medium comprises program code. The program code can be loaded and executed by a processor. When the processor executes the program code, it causes the processor to carry out a method for processing status data. The method comprises obtaining initial status data. Initial status data describe one or more operating variables of the battery. The method also comprises applying a first neural network to the initial status data. In this way, an encoded representation of the initial status data is obtained. Furthermore, the method comprises carrying out an aging estimation based on the encoded representation of the initial status data. A status indicator is obtained therefrom, which is indicative of an aging status of the battery. This carrying out of the aging estimation comprises applying a second neural network to the encoded representation of the initial status data.

A method of training a first neural network is provided. The first neural network is configured to provide an encoded representation of the initial status data based on initial status data. The initial status data describe one or more operating variables of the battery. The method comprises applying a second neural network to the encoded representation of the status data. In this way, reconstructed status data are obtained. In addition, the method comprises applying a third neural network to the encoded representation of the status data to obtain a status indicator. This status indicator is indicative of an aging status of the battery, for example at the current point in time for which the one or more operating variables are described by the status data, or alternatively or additionally for a future point in time. The method furthermore comprises determining a loss function for training the first neural network based on a comparison of the reconstructed status data to the initial status data. The loss function is furthermore determined based on a comparison of the status indicator to a corresponding reference value. The method also comprises training the first neural network based on the loss function. Optionally, it would also be conceivable for the second and the third neural network to be trained based on the loss function.

A device—for example a server—comprises a processor and a memory. The processor can load and execute program code from the memory. This causes the processor to carry out the method described above for training the first neural network.

The first neural network can therefore form an encoder ANN of an autoencoder ANN and the second neural network can therefore form a decoder ANN of an autoencoder ANN.

A computer program or a computer program product or a computer-readable storage medium comprises program code. The program code can be loaded and executed by a processor. When the processor executes the program code, it causes the processor to carry out a method for training a first neural network. The first neural network is configured to provide an encoded representation of the initial status data based on initial status data. The initial status data describe one or more operating variables of the battery. The method comprises applying a second neural network to the encoded representation of the status data. In this way, reconstructed status data are obtained. In addition, the method comprises applying a third neural network to the encoded representation of the status data to obtain a status indicator. This status indicator is indicative of an aging status of the battery. The method furthermore comprises determining a loss function for training the first neural network based on a comparison of the reconstructed status data to the initial status data. The loss function is furthermore determined based on a comparison of the status indicator to a corresponding reference value. The method also comprises training the first neural network based on the loss function. Optionally, it would also be conceivable for the second and the third neural network to be trained based on the loss function.

The features presented above, as well as features that are described below, can be used not only in the corresponding explicitly presented combinations, but also in further combinations or in isolation, without departing from the protective scope of the present invention.

### BRIEF DESCRIPTION OF THE FIGURES

FIG. 1 schematically illustrates a system comprising multiple batteries and a server according to various examples.

FIG. 2 illustrates details of a battery according to various examples.

FIG. 3 illustrates details of a server according to various examples.

FIG. 4 illustrates time-continuous, initial status data of a battery according to various examples.

FIG. 5 illustrates status data of a battery in the form of a load spectrum according to various examples.

FIG. 6 schematically illustrates an encoder ANN of an autoencoder ANN according to various examples.

FIG. 7 schematically illustrates a decoder ANN of an autoencoder ANN according to various examples.

FIG. 8 is a flow chart of an exemplary method according to various examples.

FIG. 9 schematically illustrates reconstructed status data in comparison to initial status data according to various examples.

FIG. 10 schematically illustrates the application of an autoencoder ANN to initial status data and the downstream further data processing of corresponding reconstructed status data according to various examples.

FIG. 11 schematically illustrates the application of an encoder ANN without a decoder ANN of an autoencoder ANN to initial status data and the subsequent further processing of an encoded representation of the initial status data according to various examples.

FIG. 12 is a flow chart of an exemplary method.

FIG. 13 schematically illustrates the training of an autoencoder ANN according to various examples.

### DETAILED DESCRIPTION OF EMBODIMENTS

The properties, features, and advantages of this invention described above, and the manner in which they are achieved, will become clearer and more easily understood in conjunction with the following description of the exemplary embodiments, which are explained in more detail in conjunction with the drawings.

The present invention will be explained in greater detail hereinafter with reference to the accompanying drawings on the basis of preferred embodiments. In the figures, identical reference numbers designate identical or similar elements. The figures are schematic representations of various embodiments of the invention. Elements depicted in the figures are not necessarily drawn to scale. Rather, the various elements shown in the figures are presented in such a way that the function and general purpose thereof can be understood by one skilled in the art. Connections and couplings between functional units and elements shown in the figures can also be implemented as an indirect connection or coupling. A connection or coupling can be implemented as wired or wireless. Functional units can be implemented as hardware, software, or a combination of hardware and software.

Techniques in conjunction with the characterization of rechargeable batteries are described hereinafter. The techniques described herein can be used in conjunction with greatly varying types of batteries, for example in conjunction with lithium-ion-based batteries, such as lithium-nickel-manganese-cobalt oxide batteries or lithium-manganese oxide batteries.

The batteries described herein can be used for batteries in different application scenarios, for example for batteries used in devices such as motor vehicles or drones or portable electronic devices such as mobile wireless devices. It would also be conceivable to use the batteries described herein in the form of stationary energy storage devices. Indoor or outdoor applications are conceivable, which differ primarily with regard to the temperature ranges. Application scenarios comprise: stationary energy storage devices in a micro-grid, energy storage devices for mobile applications, low-load energy storage devices, energy storage devices for light electric vehicles such as bicycles or scooters, energy storage devices for electric passenger vehicles, indoor applications, and outdoor applications.

The techniques described herein make it possible to control the operation of a battery in a particularly precise manner. For example, it is possible to deliberately trigger an error mode of a battery. Alternatively or additionally, the techniques described herein make it possible to ascertain a status indicator, which is indicative of an aging status (aging value) of the battery, in conjunction with the characterization of the battery. The aging value correlates with the aging of the rechargeable battery. The aging value can describe the quality of the battery (and could therefore also be referred to as the Q value). The aging value, for example, can assume greater values the further the aging of the battery has progressed. The aging value can correlate with the SOH or correspond thereto. The aging value, for example, can quantify an increase in the resistance or impedance of the battery. The aging value, for example, can quantify the decrease in the overall capacity of the battery. The aging value can be ascertained, for example, for a current actual point in time or for a future point in time, i.e., a prediction can be carried out. The aging value could, for example, indicate a remaining service life, which is defined, for example, in conjunction with a proportion of the nominal capacity and can be variable specific to the application.

According to various examples described herein, it is possible that the aging value is determined using at least one ML algorithm. An ML algorithm is characterized in that, in a learning phase, parameter values of parameters of the ML algorithm are set by means of suitable training. The training is automated and based on training data. In the present example, the training data can comprise reference status data of the battery, as well as a priori knowledge (ground truth) about the respectively associated aging value, i.e., a corresponding reference value for the aging value. Then, as part of the training, the parameter values of the ML algorithm can be adapted in such a way that, based on the training data, the ML algorithm determines an aging value that corresponds to the associated reference aging value particularly well. This therefore means that by means of the ML algorithm, a dimensionality reduction can be performed that maps the one or more state variables to a corresponding aging value. Examples of ML algorithms comprise, for example: artificial neural networks (ANNs), genetic algorithms, support vector machines, etc.

ANNs, for example, can be designed as a multi-layer feedforward network, in which the neurons of the different layers do not form loops. An example of such a multi-layer feedforward ANN is a convolutional neural network, in which convolutions of the values of the neurons are carried out using a kernel in at least some layers. Pooling layers or non-linear layers can also be provided. However, it would also be possible to use recurrent ANNs, for example to take a time series into consideration.

However, the techniques described herein are not restricted to using an ML algorithm for aging estimation. Alternatively or additionally, an empirically parameterized aging model could also be used. This means that an aging model can be used, the structure of which depicts the physical-technical properties of the battery and which has parameter values that are defined, for example, based on reference measurements or on the basis of expert knowledge. An iteratively optimizing training step as in an ML algorithm is then not necessary. An exemplary empirical aging model is described in: J. Schmalstieg, S. Käbitz, M. Ecker, and D. U. Sauer, “A holistic aging model for Li(NiMnCo)O₂ based 18650 lithium-ion batteries,” Journal of Power Sources, Vol 257, pp. 325-334, 2014.

Various examples of the techniques described herein are based on the knowledge that—essentially independent of the specific algorithmic implementation of the aging estimation—a large amount of status data that describe one or more operating variables of the battery is regularly required to carry out the aging estimation. This results in large amounts of memory if the corresponding status data are collected at a central location—such as a server or a database connected thereto. This can cause high costs for data transfer and storage, and data transfer can also be subject to restrictions due to limited network availability.

Furthermore, various examples of the techniques described herein are based on the finding that the acquisition of associated measurement data describing one or more operating variables of the battery can be subject to inaccuracies. For example, due to inaccuracies in the acquisition of corresponding measurement data, it can happen that the status data obtained therefrom are incomplete or contain errors. Examples of corresponding inaccuracies comprise, for example, signal noise in the measurement data, for example due to interfering influences of the environment on corresponding sensors that are configured to acquire the measurement data. Gaps or outliers in the status data can also be observed, for example because dead times occur during the acquisition of the measurement data or the transmission of the status data. It has also been observed that inaccuracies can occur in the status data due to offset errors. Such offset errors can occur due to systematic shifts in the measurement data. Sometimes it can happen that the time resolution of the status data is insufficient, for example because the associated measurement data has been compressed due to pre-processing or because the sampling rate of the sensors is low.

Another scenario relates, for example, to the absence of status data that describe a specific operating variable of the battery; the available status data can comprise one or more operating variables, for example, can contain a corresponding time series (for example for the cell voltage and temperature), but not a specific operating variable (for example the current flow in a cell). For example, no sensor can be provided that directly measures the corresponding operating variable (i.e., in the case of current flow, a suitable shunt resistor). Such an operating variable can also be referred to as “hidden” because it cannot be measured directly. Various examples are based on the knowledge that in such a scenario it can be desirable to derive one or more hidden operating variables from the measured operating variables or the operating variables indicated by the status data. In this way, for example, an aging estimation can be made particularly accurately by also taking into consideration one or more hidden operating variables. It would also be conceivable for the operation of the battery to be controlled on the basis of the one or more hidden operating variables, which can enable better charge management or thermal management, for example.

Finally, it has been observed that status data that describe multiple operating variables of the battery and are accordingly typically composed on the basis of multiple measurement data (where the multiple measurement data are acquired by different sensors) can suffer from reduced data synchronicity. This can mean that the time base of the various sensors that provide measurement data for different operating variables can be shifted in relation to one another, for example because there is no central synchronization.

In very general terms, it has also been observed that data inconsistencies occur with different batteries, for example based on production-related variance of the sensors acquiring the corresponding measurement data, etc.

Due to such inaccuracies in the status data, it has been observed that conventional techniques for aging estimation can only determine the aging value comparatively imprecisely or with little reliability. If the aging value is then used, for example, to control battery operation, this can negatively influence the further operation of the battery. For example, when the aging of the battery is overestimated, it can happen that comparatively strict operating boundary conditions are imposed on the operation of the battery without an actual underlying physical-technical reason, so that the user notices corresponding restrictions without this being actually necessary. If the aging of the battery is underestimated, the service life or the efficiency or the resource efficiency during operation of the battery can be reduced. Overall, the safety during the operation of the battery can be reduced if, for example, error states of the battery are not detected early.

According to various examples described herein, such disadvantages and limitations of aging estimation can be avoided or mitigated. In general, an autoencoder artificial neural network (autoencoder ANN) can be used for this purpose. An autoencoder ANN comprises an encoder ANN and a decoder ANN. During the training of the autoencoder ANN, ideal status data (i.e., for example, simulated status data or manually corrected status data that have no or only comparatively few errors as described above) or erroneous status data are used as input in the autoencoder ANN and ideal reference status data are used as reference to determine a corresponding loss function. Then the weights of one or more hidden layers of the encoder ANN and the decoder ANN can be adjusted. This training typically takes place in an iterative adjustment of the weights by an optimization algorithm until the loss function assumes an extreme value. Typically, the training can take place without monitoring. The encoder ANN outputs an encoded representation of the initial status data to which it is applied. The encoded representation can bring about a dimensionality reduction in relation to the initial status data. Such a reduction in the dimensionality (i.e., a compression) can be achieved in that the various components of the initial status data are typically not completely independent of one another, but rather correlate with one another. These correlations can be learned within the framework of the training autoencoder ANN, so that the dimensionality reduction is made possible. Such correlations can occur, for example, in that the initial status data describe multiple operating variables that correlate with one another: typically, for example, current and voltage correlate with one another during operation of a battery. Furthermore, for example, the temperature of the battery could correlate with the current flow through the battery, etc.

The encoded representation of the status data is thus obtained from the encoder ANN. The decoder ANN can then optionally be applied to the encoded representation of the initial status data as obtained from the encoder ANN. The decoder ANN can then provide reconstructed status data that correlate with the initial status data. The aging estimation can then be carried out on the basis of the reconstructed status data. A status indicator is obtained therefrom, which is indicative of the aging status of the battery (aging value).

However, it is not necessary in all the variants described here that the decoder ANN is used as part of the aging estimation—during the inference of the aging value (rather, in various examples the decoder ANN can only be used for training the encoder ANN and then no longer used during the inference phase).

In fact, in some examples, the aging estimation can also be carried out based on the encoded representation of the status data as received from the encoder ANN. This can be possible in particular if an ML algorithm is used to carry out the aging estimation, that is to say, for example, another ANN. Such a technique has the advantage that, due to the dimensionality reduction of the encoded representation of the initial status data in relation to the initial status data itself, the computing effort for carrying out the aging estimation based on the decoded representation of the status data is comparatively lower.

In general terms, various effects can be achieved by using such an autoencoder ANN. In particular, firstly, compression can be achieved in that the encoded representation of the initial status data has a dimensionality reduction in relation to the initial status data itself. This allows memory space to be saved and further data processing models to be run through more efficiently, for example in conjunction with carrying out the aging estimation. Secondly, a comparison of the reconstructed status data to the initial status data can make it possible to identify errors in the initial status data. This is because if there is a deviation between the reconstructed status data and the initial status data, this deviation can be indicative of a corresponding error. It would then be conceivable, for example, to carry out the aging estimation as a function of the one or more deviations that are detected by comparing the reconstructed status data to the initial status data. For example, a reliability of the aging estimation could be estimated in this way, specifically by the reliability of the initial status data itself being estimated by comparing the reconstructed status data to the initial status data. However, it would also be conceivable for the initial status data to be filtered or weighted as a function of the one or more detected deviations before the aging estimation is carried out. In this way it could be achieved, for example, that a range of the initial status data in which the one or more deviations are detected—and which can therefore be assumed to be erroneous—is not taken into account or is taken into account to a lesser extent when the aging estimation is carried out. This can increase the confidence level of the aging estimation. It is therefore possible to upgrade the data quality of the initial status data by appropriate correction or filtering.

It would be conceivable for the aging estimation to be carried out either as a function of the initial status data or the reconstructed status data. For example, it would be conceivable for a selection to be made between the initial status data and the reconstructed status data for carrying out the aging estimation as a function of the one or more deviations between the initial status data and the reconstructed status data. As an example: If hardly any or only minor deviations are detected, it can be concluded that the data quality of the initial status data is good. It is then possible to dispense with accessing the reconstructed status data in conjunction with carrying out the aging estimation; rather, the initial status data can be used. However, if a significant deviation is established between the initial status data and the reconstructed status data, then it may be desirable to use the reconstructed status data to carry out the aging estimation. This can be because otherwise a confidence level for the determined aging value based on the erroneous initial status data becomes particularly poor.

Alternatively or additionally to considering the detected one or more deviations between the initial status data and the reconstructed status data as part of the aging estimation, it would also be conceivable that the corresponding information—which is indicative of an error in the initial status data or a confidence level of the initial status data—is used as part of monitoring the operation of the battery itself (i.e., is not necessarily used for aging estimation). For example, an error mode for the batteries could be triggered as a function of the one or more deviations. The error mode could inform a user of the battery, for example, that maintenance of the battery or a battery management system or a corresponding telematics unit is required. For example, a sensor failure could be identified. An error in the communication interface (for example, dropouts in transmission) could be detected. The operation of the battery can be implemented particularly reliably in this way. Failures or errors in the operation of the battery can be detected. Appropriate countermeasures can be initiated in a timely manner.

In some examples it would also be conceivable that the operation of the battery itself is controlled based on the reconstructed status data. Such a control of the operation of the battery based on the reconstructed status data can in turn take place alternatively or additionally to the use of the reconstructed status data in conjunction with the aging estimation. In order to control the operation of the battery based on the reconstructed status data, it would be conceivable, for example, for the reconstructed status data—which are generated, for example, centrally on a server by using the autoencoder ANNs—to be transmitted to a battery management system of the battery, so that this system can carry out the operation of the battery—thus, for example, the control of charging or discharging processes—based on the reconstructed status data. In this way, the operation of the battery can be controlled particularly precisely and, in particular, errors in the initial status data can be compensated for.

Various variants have been described above, in which subsequent further data processing is carried out on the basis of the reconstructed status data—for example as part of carrying out the aging estimation and/or in conjunction with triggering the error mode and/or regarding the control of the operation of the battery. These techniques are described in more detail hereinafter in conjunction with the figures.

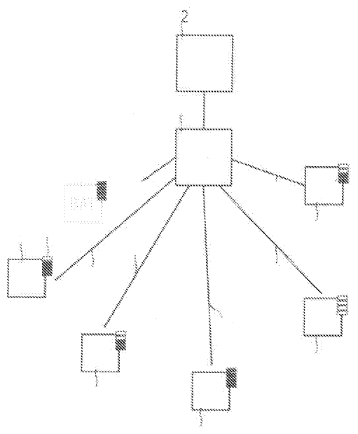

FIG. 1 illustrates aspects in conjunction with a system 80. The system 80 comprises a server 81 that is connected to a database 82. In addition, the system 80 comprises communication links 49 between the server 81 and each of multiple batteries 91-96. The communication links 49 could be implemented via a mobile wireless network, for example. For example, the batteries 91-96 can form an ensemble, i.e., they can all be of the same type.

FIG. 1 illustrates, by way of example, that the batteries 91-96 can send operational data 41 to the server 81 via the communication links 49. For example, it would be possible for the operational data 41 to be indicative of one or more status variables of the respective battery 91-96, e.g., state of charge, current flow, voltage, etc.

The operational data 41 can, as a general rule, comprise measurement data and/or status data determined on the basis of the measurement data, for example. The measurement data can be acquired by one or more sensors. For example, current measurement sensors, voltage measurement sensors, temperature sensors, pressure sensors, stress sensors, humidity sensors, etc. could be used. The measurement data can be obtained from a management system of the battery. The measurement data can quantify one or more operating states in a time-resolved manner. The status data can be determined on the basis of the measurement data. In a simple implementation, the status data can correspond directly to the measurement data. However, it would also be possible to process the measurement data in order to obtain such status data. For example, a time resolution could be changed, for example by low-pass filtering. Signal smoothing could take place. In general terms, the status data can be provided as a time-resolved series of values. Alternatively or additionally, however, it would also be conceivable for the status data to be provided as a so-called load spectrum. In this case, the frequency of occurrence of values of one or more operating variables is quantified, for example, for two or more operating variables relative to each other or also in relation to an absolute reference (e.g. a time reference or a charge/discharge cycle reference). This means that the status data provided as a load spectrum could indicate, for example, the fraction of the operating time or the operating cycles in which certain combinations of values for multiple operating variables occur during operation. In particular, the load spectrum can indicate stress factors, i.e., those operating variables that are especially relevant for aging. The load spectrum can therefore describe a load profile of the battery. Finally—alternatively or additionally to an implementation of the status data as a time-resolved series of values and/or as a load spectrum—it would be conceivable for the status data to indicate the one or more operating variables in an event-based manner. This means that the status data could indicate the one or more operating variables as a function of one or more predefined event criteria. For example, if at least one of the one or more operating variables assumes a predetermined value or range of values, then the criterion for the presence of an event could be met. In this case, the status data for a specific time window could indicate the corresponding at least one operating variable or also one or more further operating variables in a time-resolved manner around the event—corresponding time series of the measurement data can be transmitted as status data there.

FIG. 1 also illustrates, by way of example, that the server 81 can transmit control data 42 to the batteries 91-96 via the communication links 49. This allows the operation of the batteries 91-96 to be controlled. For example, it would be possible for the control data 42 to indicate one or more operating limits for the future operation of the respective battery 91-96. For example, the control data could indicate one or more control parameters for thermal management of the respective battery 91-96 and/or charging management of the respective battery 91-96. By using the control data 42, the server 81 can thus influence or control the operation of the batteries 91-96. For example, this could be based on an aging value that is ascertained by the server 81 for the respective battery. However, this could also be based on reconstructed status data obtained from the server 81 through an autoencoder ANN.

FIG. 1 also schematically illustrates a respective aging value 99 for each of the batteries 91-96 (for example, the battery 95 has aged comparatively significantly and the batteries 91, 94 have not yet aged particularly significantly). Techniques for ascertaining the aging value 99 are described hereinafter, i.e., techniques relating to carrying out an aging estimation using an autoencoder ANN.

FIG. 2 illustrates aspects in conjunction with the batteries 91-96. The batteries 91-96 are coupled to a respective device 69. This device—for example an electric motor—is powered by electrical energy from the respective battery 91-96.

The batteries 91-96 comprise or are associated with one or more management systems 61, e.g., a BMS or other control logic such as an on-board unit in the case of a vehicle. The management system 61 can be implemented by software on a CPU, for example. Alternatively or additionally, for example, an application-specific integrated circuit (ASIC) or a field-programmable gate array (FPGA) could be used. The batteries 91-96 could communicate with the management system 61 (which is then sometimes also referred to as a telematics unit) via a bus system, for example. The batteries 91-96 also comprise a communication interface 62. The management system 61 can establish a communication link 49 with the server 81 via the communication interface 62.

While FIG. 2 shows the management system 61 separately from the batteries 91-96, in other examples it would also be possible for the management system 61 to be part of the batteries 91-96.

In addition, the batteries 91-96 comprise one or more battery blocks 63. Each battery block 63 typically comprises a number of battery cells connected in parallel and/or in series. Electrical energy can be stored there.

Typically, the management system 61 can access one or more sensors in the one or more battery blocks 63. For example, the sensors can measure operating variables of the respective battery, such as the current flow and/or the voltage in at least some of the battery cells. Alternatively or additionally, the sensors can also measure other operating variables in conjunction with at least some of the battery cells, for example temperature, volume, pressure, etc. The management system 61 can then be configured to send one or more such measured values from sensors to the server 81 in the form of the operating data 41. In other words, it would be conceivable for the management system 61 to carry out pre-processing of the measurement data in order to obtain the operating data 41, so that status data are obtained; however, it would also be conceivable for the measurement data to be sent directly from the operating data 41 to the server 81. This means: The measured values can be pre-processed to a lesser or greater extent by the management system 61 before they are transmitted in the form of the operating data 41. For example, a compression would be conceivable, for example in the form of a load spectrum. Measured values could also be filtered, for example in an event-based manner.

FIG. 3 illustrates aspects in conjunction with the server 81. The server 81 comprises a processor 51 and a memory 52. The memory 52 can comprise a volatile memory element and/or a non-volatile memory element. The server 81 also comprises a communication interface 53. The processor 51 can establish a communication link 49 with each of the batteries 91-96 and the database 82 via the communication interface 53.

For example, program code can be stored in the memory 52 and loaded by the processor 51. The processor 51 can then execute the program code. The execution of the program code causes the processor 51 to perform one or more of the following processes, as they are described in detail herein in conjunction with the various examples: characterizing batteries 91-96; ascertaining an aging value 99 (for example, for the current point in time or for the prediction) for the batteries 91-96 by means of an aging estimation, for example, using an empirically parameterized model or an ML algorithm; applying an upstream algorithm to determine status data based on measurement data; training and/or applying an ML algorithm to the status data to determine the aging value, for example an autoencoder ANN; applying an encoder ANN of the autoencoder ANN and optionally a decoder ANN of the autoencoder ANN; transmitting control data to the batteries 91-96, for example to set boundary operating conditions; storing a result of a characterization or of an aging value of a corresponding battery 91-96 in a database 82; triggering an error mode for the batteries 91-96; controlling the operation of the batteries 91-96; etc.

Next, details in conjunction with possible implementations of the status data—which can be determined by the server 81 based on measurement data, for example, or which can already have been determined by the management system 61—are described.

FIG. 4 illustrates status data 201 by way of example. In the example of FIG. 4, the status data 201 indicate a time curve of the current flow 202 in one or more cells of a battery 91-96. As a general rule, however, it would be conceivable for the time curve of further or other operating variables of the batteries 91-96 to be indicated by the status data 201. The status data 201 can be obtained on the basis of measurement data that are measured by one or more sensors—for example, in the case of the current flow 202 through a shunt resistor.

The example of FIG. 4 shows that the status data 201 are obtained for a sampling interval 203. The sampling interval could, for example, be defined progressively in absolute time (“sliding window”). However, as a general rule, it would also be conceivable for the sampling interval 203 to be determined based on monitoring the state of charge of the battery. In more general terms, the measurement data are sampled based on monitoring the state of charge to obtain the status data 201. This means that the status data correspond to a specific time window of the measurement data and/or comprise a certain part of all measured values of the measurement data (such as only every second or third measured value, for example in the context of low-pass filtering). Such a sampling of the measurement data to obtain the status data 201 can ensure that subsequent ML algorithms—for example an autoencoder ANN—can process the corresponding status data, i.e., that the dimensionality of the status data corresponds to a dimensionality expected by an input of the subsequent ML algorithm. The sampling of the measurement data for obtaining the status data can—as already described above—be carried out on the server 81 or else locally on the respective batteries, for example by the management system 61 (cf. FIG. 2). Since the sampling depends on monitoring the state of charge, it can be ensured that the subsequent processing of the status data 201 by an ML algorithm—for example an auoencoder ANN—contains a significant section of the measurement data and can therefore be operated reliably and without great uncertainty. Only transferring noise or measured values in the idle state to the subsequent ML algorithm is avoided, which could result in unpredictable results.

For example, it would be conceivable that the sampling interval 203 corresponds to charge cycles of the respective battery 91-96, i.e., for example full charge, full discharge, or vice versa. Equivalent full cycles, measured against the nominal capacity (also referred to as rated capacity, i.e., the capacity that the battery has when new), could also be used as the sampling interval 203. A threshold value can thus be determined, for example, up to which the charging of the battery should have progressed by the time the sampling interval 203 is ended. The threshold could be determined as a function of the current capacity or the nominal capacity. The current capacity can be obtained by way of a previous aging estimation. Another implementation variant for determining the sampling interval 203 is based on the charge throughput: for example, the amperage could be integrated over time and, if a certain predetermined threshold value is exceeded, the sampling interval 203 can be terminated. All such techniques for determining the sampling interval enable status data that describe comparable operating sections of the battery to be transferred to the autoencoder ANN in a reproducible manner. As a result—with appropriate training using the corresponding reference status data—a particularly accurate aging estimation can be carried out.

The example of FIG. 4 illustrates that the status data 201 contain errors. In particular, FIG. 4 shows that the status data 201 have a temporal outlier 205, in which the measured values for the current flow 202 suddenly deviate from the adjacent measured values for a limited period of time. FIG. 4 additionally shows that there are no measured values for the current flow 202 in a range 206, i.e., the status data 201 are incomplete. In the example of FIG. 4, the status data 201 are also subject to noise, which can become noticeable in rapid changes in the current flow 202. These are only examples of different deficiencies of status data 201 and in different variants such deficiencies can occur individually or superimposed, or it would also be conceivable for other deficiencies of the status data 201 to be observed. According to various techniques described herein, it is possible to reliably and accurately carry out an aging estimation or other further data processing based on the erroneous status data 201 using an autoencoder ANN.

As a general rule, a wide variety of error types can occur for the initial status data, for example low time resolution (i.e., a low overall rate), low resolution of the measured values for the respective operating variable, an offset of the measured values for the respective operating variable, data synchronicity, and inconsistencies. These and other error types can be corrected using the techniques described herein in conjunction with the reconstructed status data.

However, it is not necessary in all variants for the status data 201 to be provided in a time-resolved manner, as in the example in FIG. 4. Various examples have been described above in which the status data 201 depict an operating variable—in the example in FIG. 4 the current flow 202—in a time-resolved manner. This is solely an example. In other examples, as shown in FIG. 5, it would also be conceivable for status data 210 to be provided in the form of a load spectrum. The operating variables depth of discharge 212 and state of charge 211 are correlated with one another. The corresponding values indicate the—typically relatively defined—frequency of operation of the respective battery 91-96 for the respective operating variables 211, 212 (with a relatively defined frequency, the assumption is that the load profile of the battery and thus the load spectrum for a specific intended purpose of the battery remains constant, i.e., has no change over time). However, the status data 210 does not provide a time resolution.

In the various examples described herein, such status data 201, 210 can be processed by means of one or more ML algorithms. In particular, it is possible for processing to take place using an autoencoder ANN. Details of the autoencoder ANN will be described next in conjunction with FIG. 6 to FIG. 8.

FIG. 6 illustrates a part of the autoencoder ANN, namely an encoder ANN 311, which has multiple hidden layers 312. Examples of such layers 312 can be, for example: activation layers, RNN layers, or dense layers. The number of neurons per layer 312 can vary. The encoder ANN 311 is applied to an input 301 which can be provided, for example, in the form of the status data 201 in the sampling interval 203 and/or in the form of status data 210 as a load spectrum. An output 321 is obtained from the encoder ANN 311 which then corresponds to an encoded representation of the input 311. The output 321 has a dimensionality reduction in relation to the input 301.

FIG. 7 illustrates aspects in conjunction with the autoencoder ANN, and in particular in conjunction with the decoder ANN 361. The decoder ANN 361 also has multiple hidden layers 362, which can have a different number of neurons. Again, for example, one or more of the following layers can be used: activation; RNN; dense An output 371 is shown as being obtained from the decoder ANN 361 when it is applied to an input 351. The input 351 of the decoder ANN 361 can correspond to the output 321 of the encoder ANN 311 in various examples, in particular when the full functionality of the autoencoder ANN is used. In such a case, the output 371 of the decoder ANN then corresponds to a reconstructed variant of the input 301 into the encoder ANN. This means that, for example, when the encoder ANN 311 is applied to status data 201, 210 that describe one or more operating variables of a battery 91-96, reconstructed status data can be obtained as output 371.

It is described hereinafter in conjunction with FIG. 8 how, by using such autoencoder ANN techniques as described in conjunction with FIG. 6 and FIG. 7, advantageous effects can be achieved in conjunction with the processing of the status data 201, 210.

FIG. 8 is a flow chart of an exemplary method. The method can be executed entirely on the server 81, for example, but it would also be possible for the method to be executed entirely on a management system 61 of one of the batteries 91-96. Combined variants would also be conceivable, in which individual steps of the method from FIG. 8 are executed on the management system 61 associated with one of the batteries 91-96, and further steps are executed on the server 81. The method of FIG. 8 can be executed, for example, by a processor based on program code which it loads from a non-volatile memory (cf., for example, FIG. 3: processor 51 and memory 52).

In FIG. 8, optional steps are identified by dashed lines.

First, in optional block 3005, measurement data is pre-processed in order to obtain initial status data. For example, different operations could be applied in the period of time and/or frequency space, e.g., a sampling, a high-pass filter, a low-pass filter, etc. For example, it would be conceivable that the sampling is carried out depending on a monitoring of the charging/discharging of the respective battery 91-96, i.e., the state of charge of the battery is monitored and the sampling is carried out based on the monitoring of the state of charge. Details in conjunction with the sampling have been discussed above, for example in conjunction with FIG. 4.

In the scope of block 3005, it would also be conceivable to accumulate measured values or to create a load spectrum within the scope of a histogram approach, as described above in conjunction with FIG. 5.

The initial status data obtained in this way or then encoded in block 3010 by means of an encoder ANN, i.e., the encoder ANN is applied to the initial status data in order to obtain an encoded representation of the initial status data in this way. Corresponding techniques in conjunction with the encoder ANN were described above in conjunction with FIG. 6.

Once the encoded initial status data have been obtained from block 3010, block 3015 can then be carried out. For example, it would be conceivable for blocks 3005 and 3010 to be carried out on a management system 61 of the respective battery 91-96, cf., for example, FIG. 2. It would then be conceivable that in the scope of block 3015, the encoded status data obtained in this way—which are reduced in size in comparison to the initial status data—are transmitted to the server 81 via the communication link 49 (cf. also FIG. 1). Alternatively or additionally, it would be conceivable for the coded representation of the initial status data to be temporarily stored, for example in the database 82. Such temporary storage can be used, for example, to be able to delay carrying out the aging estimation, for example until enough instances of the initial status data or decoded initial status data have been obtained in order to be able to carry out an accurate aging estimation with a sufficiently large data foundation. In any case, it can be beneficial that the size of the encoded initial status data is reduced in comparison to the initial status data in order to conserve computing resources and memory resources.

In FIG. 8, two variants are then shown, namely once according to branch 3020-3025; and once according to branch 3030. First, the variant according to branch 3020-3025 is described.

In this variant according to branch 3020-2025, the decoding of the encoded representation of the initial status data takes place in block 3020, namely in that a decoder ANN (cf. FIG. 7) is applied to the encoded representation of the initial status data. The decoder ANN then provides reconstructed status data. The reconstructed status data can then be evaluated in block 3025, for example by carrying out an aging estimation based on the reconstructed status data in order to obtain an aging value that is indicative of the aging status of the battery. As a general rule, the aging value can be indicative of the actual aging condition at the current point in time, to which the status data relate. Alternatively or additionally, however, it would also be conceivable for the aging estimation to make a prediction for the aging value, thus to determine the aging value for a point in time that is before the most recent point in time, to which the status data relate. Alternatively or additionally to such an evaluation of the reconstructed status data for the purpose of aging estimation, it would be possible, for example, for an error mode of the battery to be resolved as a function of the reconstructed status data. This is because in this context, it would be possible in particular for the reconstructed status data to be compared to the initial status data in order to detect one or more deviations. If one or more deviations are detected, the error mode can be triggered. Specifically, the deviations can be indicative of the fact that the initial status data contain errors, i.e., for example, have outliers 205 or gaps 206 (as described, for example, in conjunction with FIG. 4). Such errors in the initial status data can be indicative of problems in the operation of the battery and accordingly it can be helpful to trigger the error mode. Alternatively or additionally to triggering the error mode in this way, it would also be possible for the battery operation to be controlled within the scope of block 3025 and based on the reconstructed status data, namely, for example, by sending corresponding control data 42 to the respective battery 91-96 (cf. FIG. 1). This is because the reconstructed status data can, for example, be corrected and/or reconstructed in comparison to the initial status data. This is shown in conjunction with FIG. 9.

The example of FIG. 9 basically corresponds to the example of FIG. 4: Specifically, FIG. 9 also shows the initial status data 201 (solid line). Furthermore, FIG. 9 also shows the reconstructed status data 209 (dotted line) obtained by using an autoencoder ANN comprising an encoder ANN 311 and a decoder ANN 361. It is apparent from FIG. 9 that the outlier 205 is corrected and the range 206 in which no initial status data 201 are present is reconstructed.

Compensating for an outlier 205 or compensating for a range 206 in which the status data are missing—as described above—are only examples of error types of the initial status data 201, which can be compensated for by the examples described herein in conjunction with the autoencoder ANN. Further examples of error types of the initial status data 201 would be, for example, detection or compensation for erroneous measured values. It could be described as an example that, for example, a temperature sensor has a malfunction, wherein the temperature sensor continues to provide (erroneous) measurement data, however. In the context of this malfunction, the correlation between a time series of temperature measurement data and another time series of current measurement data is systematically different from a corresponding correlation that is observed in normal operation. This can be detected by using the autoencoder ANN. For example, an error mode could then be triggered, or it would also be conceivable for corrected temperature measurement data to be output.

Referring again to FIG. 8: it was thus described how the operation of the batteries 91-96 can be controlled on the basis of the reconstructed status data 209 or how an error mode can be triggered. In the various examples, it would also be conceivable for the aging estimation of the corresponding battery 91-96 to be carried out based on the reconstructed status data, in particular a comparison of the reconstructed status data 209 to the initial status data 201. The aging estimation can be carried out as a function of one or more deviations (illustrated by the arrows in FIG. 9) between the initial status data 201 and the reconstructed status data 209. For example, it would be conceivable that either the initial status data 201 or the reconstructed status data 209—depending on whether the aging estimation is carried out based on the initial status data 201 or based on the reconstructed status data 209—are filtered and/or weighted before the aging estimation is carried out, i.e., before a corresponding algorithm (for example another ANN or an empirically parameterized model) is applied to the internal status data 201, 210 or the reconstructed status data 209. In this way it is possible that the aging estimation considers ranges in the respective status data 201, 210, 209 that are associated with greater inaccuracy (this is typically the case where the deviation between the initial status data 201, 210 and the reconstructed status data 209 is large) less strongly in the context of the aging estimation. As a result, the aging estimation can also be carried out more precisely.

It would also be possible, for example, for either the initial status data 201, 210 or the reconstructed status data 209 to be selected for carrying out the aging estimation as a function of these deviations.

A variant as illustrated in conjunction with branch 3020-3025 in FIG. 8 is also shown in conjunction with FIG. 10. FIG. 10 shows the autoencoder ANN 310, which comprises the series connection of encoder ANN 311 and decoder ANN 361. The initial status data 201, 210 are used as the input 301 into the autoencoder ANN 310 and the reconstructed status data 209 are then obtained as the output 371 from the autoencoder ANN 310. The encoded representation 208 of the initial status data 201, 210 is also shown.

One or more algorithms 411 can then be applied to the reconstructed status data 209, for example, for post-processing. Both empirically parameterized algorithms and ML algorithms, for example ANNs or support vector machines, come into consideration as the algorithms 411.

The one or more algorithms can provide an output 421 in the form of an aging value, i.e., carry out an aging estimation (cf. FIG. 1, aging value 99). Alternatively or additionally, the output 421 could also relate to control data 42 (cf. FIG. 1), and in this way could control operation of the batteries 91-96. A trigger signal for the error mode could also be output.

FIG. 10 also shows that in some examples the one or more algorithms 411—additionally or alternatively to the output 371 of the autoencoder ANN 310— also can be applied to the initial status data 201, 210, i.e., the input 301 into the autoencoder ANN 310. For example, a selection between the different input paths could be made as a function of the deviations between the reconstructed status data 209 and the initial status data 201, 210.

Referring again to FIG. 8: As shown in conjunction with branch 3030, it is not necessary in all variants for the encoded representation 208 of the initial status data 201, 210 to be decoded. Rather, it would be conceivable that the data evaluation in block 3030 is carried out based on the encoded representation 208 of the initial status data 201, 210. As a general rule, the data evaluation in block 3030 can basically correspond to the data evaluation in block 3025, i.e., for example, relate to an aging estimation, relate to the execution of a failure mode, and/or relate to controlling the operation of a battery.

A corresponding variant according to branch 3030 of the method of FIG. 8 is also illustrated in conjunction with FIG. 11. It is shown therein that only the encoder ANN 311 is used by the autoencoder ANN 310 and then a subsequent algorithm 431 for data evaluation—implemented here as an ANN having multiple different hidden layers—is applied to the output of the encoder ANN 311, i.e., decoded initial status data 208.

Various techniques have been described above in order to to encode the status data 201, 210 and then evaluate them by means of the autoencoder ANN 310. This corresponds to the inference, for example to determine the aging value—which cannot be measured directly—or to ascertain other derived variables. Referring to FIG. 12, where an exemplary method is shown, this corresponds to inference block 3115.

Before carrying out the inference in block 3115, the autoencoder ANN 310 can be trained in block 3110. This means that the different weights of the neurons in the different layers of the encoder ANN 311 and in the different hidden layers 362 of the decoder ANN 361 are adjusted by means of an iterative optimizing method, which takes into consideration a loss function. Examples of a variant of training the autoencoder ANN 310 are described hereinafter in conjunction with FIG. 13.

As a general rule—during the training (cf. FIG. 12: block 3110)—the input 301 into the autoencoder ANN 310 can comprise ideal status data (i.e., provided without or without significant error inclusions), or also status data which include errors, i.e., have, e.g., gaps, jumps, noise, etc. Ideal status data matching the status data used as the input 301 can be used as a reference (i.e., as ground truth). The loss function can then be formed from a comparison of the output 371 of the autoencoder ANN 310 to these ideal status data, and the weights can be adjusted accordingly. For example, backward propagation could be used. An iterative numerical optimization with adjustment of the weights can be used.

The specific case of training according to the example of FIG. 13 will now be explained. A loss function 391 based on the output 371 of the autoencoder ANN 310 is also formed there. For example, the loss function 391 can determine a difference between the output 371 of the autoencoder ANN 310 and ideal status data (ground truth) corresponding to the status data used as the input 301. In the example of FIG. 13, when determining the loss function 391, the output 421 of a further neural network 431 is also taken into consideration. This further neural network 431 has already been described in conjunction with FIG. 11 and makes it possible to carry out a data evaluation based on the reconstructed status data that are received as the output 321 of the encoder ANN 311. For example, an aging value could be determined by means of the ANN 431. This aging value could then be compared to a reference aging value (ground truth)—determined, for example, by means of laboratory measurements—and the loss function 391 can be determined based on this comparison.

In this way it can be ensured that the coding in the encoder ANN 311 takes place in such a way that it is then possible to carry out a meaningful inference regarding the aging value in conjunction with the aging estimation by means of the ANN 431.

Not only can the loss function 391 be used to train the encoder ANN 311, but rather it could also be used to train the ANN 431. The loss function can also be used to train the decoder ANN 361. This is represented in FIG. 13 by the corresponding feedback arrows.

In summary, techniques have been described above which make it possible to collect status data at a central point. An autoencoder ANN can then be applied to the status data: this can comprise applying an encoder ANN of the autoencoder ANN, and optionally applying a decoder ANN of the autoencoder ANN.

The use of the autoencoder ANN can be based on time-continuous status data and can upgrade them, i.e., for example, reconstruct flaws or correct flaws. This can ensure error-free, safe, and efficient operation in conjunction with the aging estimation or other applications such as the operation of the batteries themselves.

Obviously, the features of the embodiments and aspects of the invention described above can be combined with one another. In particular, the features can be used not only in the combinations described, but also in other combinations or in isolation, without departing from the field of the invention.

1-16. (canceled)

17. A method for processing status data of a battery, wherein the method comprises:
obtaining initial status data describing one or more operating variables of the battery,
applying a first neural network to the initial status data in order to obtain an encoded representation of the initial status data,
applying a second neural network to the encoded representation of the initial status data in order to obtain reconstructed status data, and
carrying out an aging estimation based on the reconstructed status data in order to obtain a status indicator which is indicative of an aging status of the battery.

18. The method of claim 17, wherein the method furthermore comprises:
comparing the reconstructed status data to the initial status data in order to identify one or more deviations,
wherein the aging estimation is carried out as a function of the one or more deviations.

19. The method of claim 18, wherein the method furthermore comprises:
filtering and/or weighting the initial status data and/or the reconstructed status data before carrying out the aging estimation and in a range in which the one or more deviations are detected.

20. The method of claim 18, wherein the method furthermore comprises:
triggering an error mode for the battery as a function of the one or more deviations.

21. The method of claim 18, wherein the method furthermore comprises:
selecting the initial status data or the reconstructed status data for carrying out the aging estimation as a function of the one or more deviations,
wherein the aging estimation is then carried out based on the reconstructed status data if these are selected.

22. The method of claim 17, wherein the method furthermore comprises:
controlling the operation of the battery based on the reconstructed status data.

23. The method of claim 17, wherein the method furthermore comprises at least one of the following steps:
transmitting the encoded representation of the initial status data from a memory associated with the battery to a central memory for server-side further processing, and/or
temporarily storing the encoded representation of the initial status data until further processing.

24. The method of claim 17, wherein the method furthermore comprises at least one of the following steps:
transmitting the encoded representation of the initial status data from a memory associated with the battery to a central memory for server-side further processing, and/or
temporarily storing the encoded representation of the initial status data until further processing.

25. The method of claim 17,
wherein the initial status data resolve a time curve of the one or more operating variables of the battery,
wherein the method furthermore comprises:
monitoring the state of charge of the battery,
wherein the initial status data are obtained based on a sampling of measurement data of the battery describing the one or more operating variables, wherein the sampling depends on the monitoring of the state of charge.

26. The method of claim 17,
wherein the initial status data describe a load spectrum of one or more operating variables of the battery.

27. The method of claim 17,
wherein the initial status data comprise one or more time series of the one or more operating variables of the battery,
wherein the reconstructed status data comprise at least one further time series of at least one further operating variable of the battery,
wherein the initial status data do not comprise at least one further time series.

28. A method for processing status data of a battery, wherein the method comprises:
obtaining initial status data describing one or more operating variables of the battery,
applying a first neural network to the initial status data in order to obtain an encoded representation of the initial status data, and
carrying out an aging estimation based on the encoded representation of the initial status data in order to obtain a status indicator which is indicative of an aging status of the battery,
wherein carrying out the aging estimation comprises applying a second neural network to the encoded representation of the initial status data.

29. The method of claim 28, wherein the method furthermore comprises at least one of the following steps:
transmitting the encoded representation of the initial status data from a memory associated with the battery to a central memory for server-side further processing, and/or
temporarily storing the encoded representation of the initial status data until further processing.

30. The method of claim 28,
wherein the initial status data resolve a time curve of the one or more operating variables of the battery,
wherein the method furthermore comprises:
monitoring the state of charge of the battery,
wherein the initial status data are obtained based on a sampling of measurement data of the battery describing the one or more operating variables, wherein the sampling depends on the monitoring of the state of charge.

31. The method of claim 28,
wherein the initial status data comprise one or more time series of the one or more operating variables of the battery,
wherein the reconstructed status data comprise at least one further time series of at least one further operating variable of the battery,
wherein the initial status data do not comprise at least one further time series.

32. The method as claimed in claim 31,
wherein the one or more operating parameters of the battery comprise: voltage at at least one battery cell of the battery and temperature;
wherein the at least one further operating variable comprises: current flow at the at least one battery cell.

33. A method for processing status data of a battery, wherein the method comprises:
obtaining initial status data describing one or more operating variables of the battery,
applying a first neural network to the initial status data in order to obtain an encoded representation of the initial status data,
applying a second neural network to the encoded representation of the initial status data in order to obtain reconstructed status data, and
comparing the reconstructed status data to the initial status data in order to identify one or more deviations, and
controlling the operation of the battery based on the reconstructed status data.

34. The method of claim 33,
wherein controlling the operation of the battery comprises triggering an error mode for the battery as a function of the one or more deviations.

35. The method as claimed in claim 34,
wherein the initial status data comprise one or more time series of the one or more operating variables of the battery,
wherein the reconstructed status data comprise at least one further time series of at least one further operating variable of the battery,
wherein the initial status data do not comprise the at least one further time series.

36. The method as claimed in claim 33,
wherein the initial status data describe a load spectrum of one or more operating variables of the battery.
